(19) United States
(12) Patent Application Publication
(10) Pub. No.: US 2026/0305499 A1
(43) Pub. Date: Oct. 1, 2026

(54) HIGH BANDWIDTH 3D MESH INTERCONNECT STRUCTURE

(71) Applicant: Atum Works Inc., Mountain View, CA (US)

(72) Inventors: Lucas Layne Brass Pabarcius, Woodside, CA (US); Malcolm George Adams Tisdale, Palo Alto, CA (US); Matteo Kimura, Emerald Hills, CA (US)

(21) Appl. No.: 19/427,275

(22) Filed: Dec. 19, 2025

Related U.S. Application Data
(60) Provisional application No. 63/737,817, filed on Dec. 23, 2024.

(51) Int. Cl. H10W 90/00; H10W 72/00; H10W 72/50; H10W 72/59

(52) U.S. Cl. CPC H10W 90/754; H10W 72/523; H10W 72/535; H10W 72/5445; H10W 72/553; H10W 72/59; H10W 90/753; H10W 72/01515

(57) ABSTRACT

A device includes an interconnect structure comprising an at least partially annular conductive wire disposed about an insulator. The device includes a first contact pad at a first surface of an element, wherein the wire extends from the first contact pad in a direction non-parallel to the first surface and connects to a second contact pad.

### RELATED APPLICATIONS

This application claims priority to U.S. Patent Application 63/737,817, filed Dec. 23, 2024, which is incorporated herein by reference.

### BACKGROUND

### Field

The field relates to microelectronic packaging and assemblies.

### Description of the Related Art

The increase in the number of electrical components to be interconnected in a microelectronic package or semiconductor assembly has resulted in an increasing need for microelectronic components to accommodate the various and dense electrical interconnections to be made. As such, package design has become more complex and correspondingly more expensive. Thus, an interconnect structure that can accommodate the various electrical connections that can be fabricated in a relatively low-cost, high-throughput process is needed.

### BRIEF DESCRIPTION OF THE DRAWINGS

Features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A-1D are schematic views showing a process for fabricating a 3D mesh structure of an interconnect structure, according to one embodiment. FIG. 1A shows a surface having a plurality of conductive contact pads. FIG. 1B shows a plurality of struts formed over the conductive contact pads. FIG. 1C illustrates a magnified view of a conductive contact pad with a strut, and FIG. 1D shows selective coating of the strut.

FIGS. 2A-2F are schematic views of a strut in different possible fabrication stages, according to one embodiment. FIG. 2A illustrates an initial stage of polymerization, where the dimensions of the polymerized portion depend on the specifications of the instrumentation. FIG. 2B illustrates a polymerized strut. FIG. 2C shows a strut coated with a conductive material and FIG. 2D illustrates the coated strut of FIG. 2C in a bulk dielectric. FIG. 2E shows the strut of FIG. 2C with an insulator coating or barrier coating over the conductive material and FIG. 2F illustrates this insulated strut in a bulk dielectric.

FIG. 3 is a schematic cross section of a microelectronic package having three dies to be electrically connected with an interconnect structure, according to one embodiment.

FIGS. 4A-4G are schematic cross sections of a process of forming a microelectronic package having a 3D mesh interconnect structure, according to one embodiment.

FIG. 5 is a schematic cross section of a microelectronic package having three dies to be electrically connected with a 3D mesh interconnect structure, according to one embodiment.

FIG. 6A is a schematic cross section of an interconnect structure having a substrate core including a plurality of through-substrate vias, according to one embodiment. FIG. 6B is a schematic cross section of an interconnect structure having a transparent substrate core including a plurality of through-holes, according to one embodiment.

Like reference numbers are used to describe like features throughout the description and drawings.

### DETAILED DESCRIPTION

Although several embodiments, examples, and illustrations are disclosed below, it will be understood by those of ordinary skill in the art that the innovative aspects described herein extend beyond the specifically disclosed embodiments, examples, and illustrations and include other uses and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments. In addition, the embodiments can comprise several novel features and no single feature is solely responsible for its desirable attributes or is essential to practicing the innovative aspects herein described.

Microelectronic packaging has become increasingly complex and expensive, especially with the increase in components to be included and electrically connected in such packages. In comparison to the rate of improvements to transistor scaling, the rate of improvements to interconnect bandwidth has been slower. The slower progress can be attributed to density limitations and/or shoreline constraints (e.g., constraints having to do with the limited physical (perimeter) space for chip-to-chip connections). Overcoming these issues can be accomplished by improving microelectronic packaging (e.g., system integration) to tightly integrate high-density interconnects in a three-dimensional (3D) approach, which would enable interconnect counts to scale with a device area rather than the device perimeter. Chipletization shows promise as one avenue to reduce the cost of fabricating advanced chips, but this approach utilizes high-yield, cost-effective, and high-density interconnect packaging technologies.

An interconnect structure, such as a high-bandwidth 3D mesh interposer, can be implemented as a high-density interconnect packaging technology. Such an interconnect structure can be fabricated using a maskless, multi-material, 3D lithography process, which can fabricate these interconnect packaging components at high yield for relatively low process cost. Unlike conventional packaging technologies, the interconnect structures described herein can be fabricated to have substantially more layers than might be found in conventional packages. For example, the interconnect structure can have a metal layer count on the order of tens or even thousands, allowing for efficient ultra-high bandwidth density connectors. With the substantial increase in the number of layers in one interconnect structure as compared to conventional packages, the interconnect structure described herein can operate below radio frequency (RF) data rates, which reduces overhead and increases efficiency as compared to high-speed RF connectors. Additionally, the interconnect structure technology described herein can undergo an in-situ fabrication process, such that the interconnect structure technology can be fabricated directly onto the chiplets to be electrically connected.

A flexible packaging connector technology or lithography process is used to fabricate an interconnect technology that can achieve shoreline bandwidth density values greater than 20 Tb/s/mm with low power consumption with values less than 0.1 pJ/bit at interconnection distances exceeding 25 mm. Advances in lithography processes and instrumentation are making it possible to achieve highly parallelized, low-temperature processes, which, as described herein, can be used for the selective metallization of photopolymers. The processes that can be implemented to fabricate a high-bandwidth, 3D mesh interconnect structure (or interposer) are based on modulation of light to polymerize a layer of photoresist. Microstereolithography employs single-photon absorption (SPA). In SPA, a single photon, typically in the ultraviolet (UV) range, is absorbed by a photoinitiator molecule, which excites the molecule from a ground state to an excited state. From there, radical formation can occur through homolytic cleavage (e.g., Type I photoinitiators) or hydrogen abstraction (e.g., Type II photoinitiators), which can then lead to cross-linking reactions. Thus, SPA facilitates a chemical reaction that results in the formation of a cross-linked polymer within the irradiated region.

Conventional lithography processes rely on single-photon absorption (SPA). In these processes, photons are absorbed along the entirety of the light path through a photosensitive resin. Generally, a two-dimensional (2D) pattern can be transferred to a surface of a substrate with direct writing or with implementation of a mask. In contrast, 3D lithography processes (e.g., interference lithography, microstereolithography, multi-photon lithography processes, one-plus-one photon lithography, light-sheet 3D printing, continuous liquid interface printing, and tomographic volumetric additive manufacturing) are able to localize photopolymerization within a specific point or points along the light path in the photoresist. Chemical and optical non-linearities can be used to define structures with a feature size below the diffraction limit intrinsic to the light source. For example, in lithography processes implementing multi-photon polymerization (MPP), photon absorption occurs within the focal spot of the laser beam, which yields a more precise structure formation with smaller feature sizes, than would be achieved with processes utilizing SPA. Micron-scale or even nano-scale features can be obtained, and 3D structures like micropillars, nanopillars, complex, micron-scale lattice structures, micro-optics, and more can be fabricated.

An optical set-up for microstereolithography (μSL) can generally include a laser, beam-steering optics, and focusing elements. For example, the laser can be selected to produce light at wavelengths in the ultraviolet (UV) range, such as 355 nm or 405 nm, corresponding to absorption peaks of common photoinitiators. In some cases, the laser can be continuous (e.g., CW) or pulsed (e.g., a Q-switched laser). The light generated from the laser is propagated along an optical path through elements like a beam expander, galvanometer mirrors (e.g., galvo scanners), telecentric optics (e.g., f-theta lenses), and any other suitable optical components. In some implementations, the optical path includes a digital micromirror device (DMD) or liquid crystal display (LCD) to enable projection-based layer curing rather than point-by-point vector scanning. The photosensitive resin is typically positioned on a build platform that translates vertically (e.g., a z-stage) to enable sequential layer formation, with each layer polymerized at or near the resin surface through single-photon absorption.

An optical set-up for maskless, multi-material, MPL can generally include a laser, directing and light-shaping optics, and an objective (e.g., a high numerical aperture (NA) objective). For example, the laser can be selected to produce light at wavelengths in the ultraviolet (UV) range, such as ultraviolet, green, red, and infrared. In some cases, the laser can be continuous (e.g., CW) or pulsed (e.g., a femtosecond-pulsed laser). The light generated from the laser is propagated along an optical path through elements like an acousto-optic modulator (AOM), an acousto-optic deflector (AOD), a digital micromirror device (DMD), collimators, 4f optics, a spatial light modulator (SLM), an objective (e.g., 100×, 1.2 NA objective), and any other suitable optical components. In some cases, a portion of the optical path is parallelized to facilitate a plurality of laser beams at the sample (e.g., the photosensitive resin) that can simultaneously proceed with MPP.

### High-Bandwidth, 3D Mesh Interconnect Structure

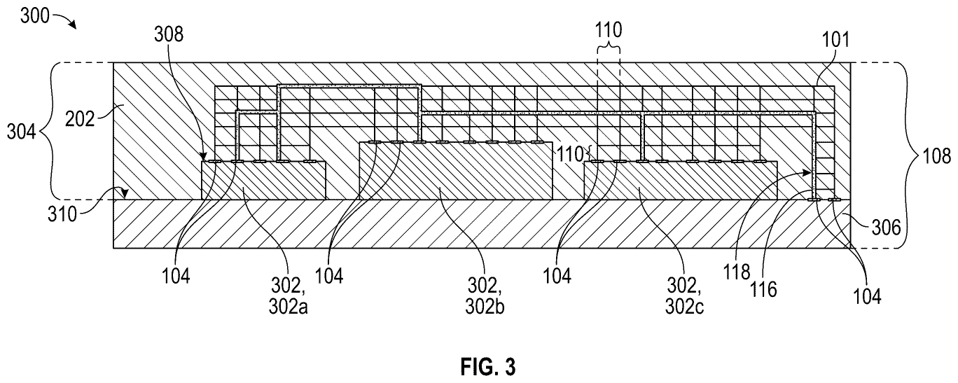

A mesh wiring interconnect structure (e.g., an interposer, advanced package, or package) for electronic devices is described herein. 3D lithography or any other processes or techniques capable of similar additive manufacturing processes (e.g., projection microstereolithography (PSL), interference lithography, microstereolithography, multi-photon lithography processes, one-plus-one photon lithography, light-sheet 3D printing, continuous liquid interface printing, and tomographic volumetric additive manufacturing) can be implemented to create a dense three-dimensional (3D) scaffold or mesh of wires, where the wires comprise an interior structure that is an insulating material, such as polymerized resin. Then, the conductive aspects of the wires can be selectively grown radially outwards from the interior insulating material. The mesh wiring, which comprises a conductive coating over a dielectric core, can subsequently be implemented to electrically connect two or more devices across an electronic system. In some embodiments, the conductive wires formed from 3D lithography processes can be implemented in a variety of applications (e.g., a variety of RDL applications). For example, the wires can connect two or more dies or devices (e.g., FIGS. 3-5), or connect conductive contact pads within a single die or wafer, or connect conductive contact pads within a substrate, or connect to through-substrate vias within a substrate, or connect a substrate to a die. In some cases, the wiring can facilitate an electrical connection between any two conductive contact pads within a package, independent of the pad locations.

The interconnect structure can include or be formed on a carrier element or substrate having a first surface that includes a plurality of conductive contacts or a plurality of conductive contact pads. In some cases, the carrier or substrate remains a part of the final device. In such cases, the carrier or substrate can be attached (e.g., soldered) to another device (e.g., a system substrate, a reconstituted structure, or larger die/wafer, etc.). In some cases, the substrate or carrier can be removed, leaving behind the plurality of conductive contacts or conductive contact pads to which a scaffold or framework is connected. A scaffold or framework that has a lattice structure can be formed over the carrier element or substrate, such that the lattice structure couples to and extends from at least a portion of the plurality of conductive contact pads. The lattice structure comprises a polymerized photoresist that makes up the plurality of struts. The struts can be selectively coated with a conductive film (e.g., selectively metallized), and the scaffold encapsulated with a dielectric material.

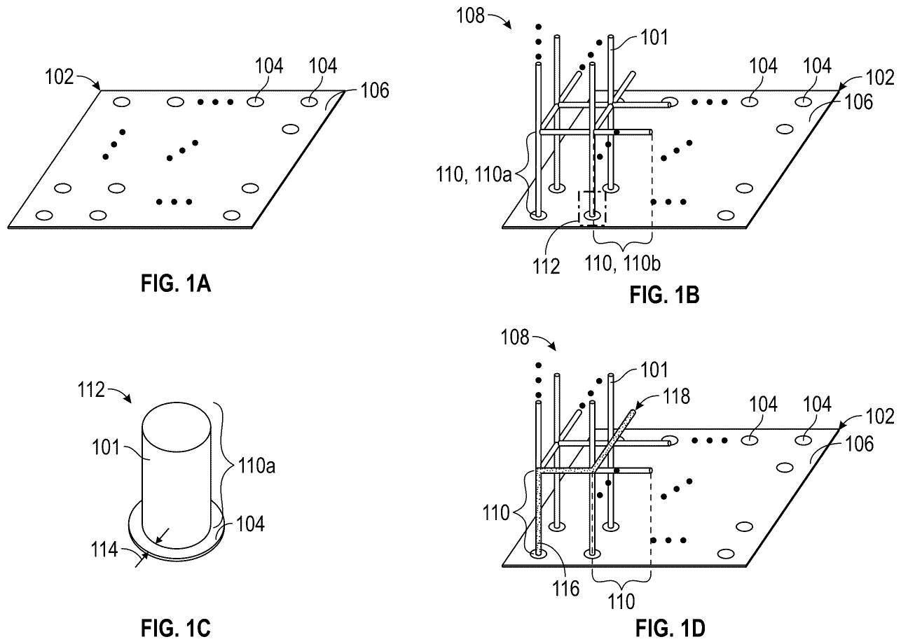

FIGS. 1A-1D are schematic views showing at a high-level, a process for fabricating a 3D lattice (or mesh) structure that can be implemented as an interconnect structure, according to one embodiment. The structural wires that make up the lattice structure of the interconnect structure are formed onto a surface 102. The surface 102, shown in FIG. 1A, can be the surface of a carrier element, a substrate (e.g., a semiconductor substrate, a ceramic substrate, an organic substrate, a printed circuit board substrate, any type of packaging substrate, etc.), a surface of a semiconductor element (e.g., a device, singulated device die or chip, chiplet, or a wafer), a reconstituted structure, or any other suitable carrier. In some cases, in which the carrier comprises a semiconductor element, the semiconductor element comprises active circuitry with transistors. In other embodiments, the carrier can comprise passive devices including capacitors, resistors, inductors, etc., or a passthrough substrate with no functional devices. A plurality of electrical contacts or conductive contact pads 104 are at or at about the surface 102, and a dielectric material 106 intervenes between the conductive contact pads 104. In various embodiments, the contact pads 104 can comprise any suitable conductive contact feature configured to serve as an electrical terminal for circuitry or a device. For example, as used herein, contact pads can comprise discrete conductive shapes formed in a dielectric layer and connecting to conductive vias and/or traces that route to circuitry, exposed ends of conductive vias, or any other suitable electrical terminal or input/output feature. In some cases, the conductive contact pads 104 can comprise copper, aluminum, gold, silver, cobalt, ruthenium, molybdenum or any other suitable conductor. For example, the surface 102 could correspond to a backside of a die having a plurality of electrical contacts. Although the surface 102 is illustrated as having a periodic configuration of conductive contact pads 104, the arrangement can be non-uniform or non-periodic. The pitch of the conductive contact pads 104 can be between approximately 400 nm and 1000 μm, such as 3 μm, or 935 μm. In some cases, the diameters of the conductive contact pads 104 can be between approximately 300 nm and 1000 μm, or between 300 nm and 500 μm, or between approximately 2 μm and 200 μm. In some cases, the distance between two conductive contact pads 104 that are electrically connected with a wire or structural wire can be between approximately 400 nm and 600 mm. Beneficially, in some embodiments, such structural wires can electrically connect conductive contact pads 104 at relatively large distances, such as at about 600 mm.

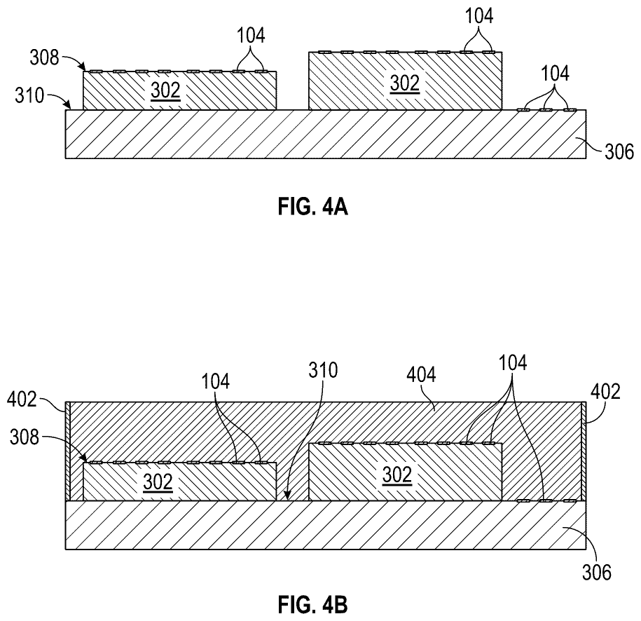

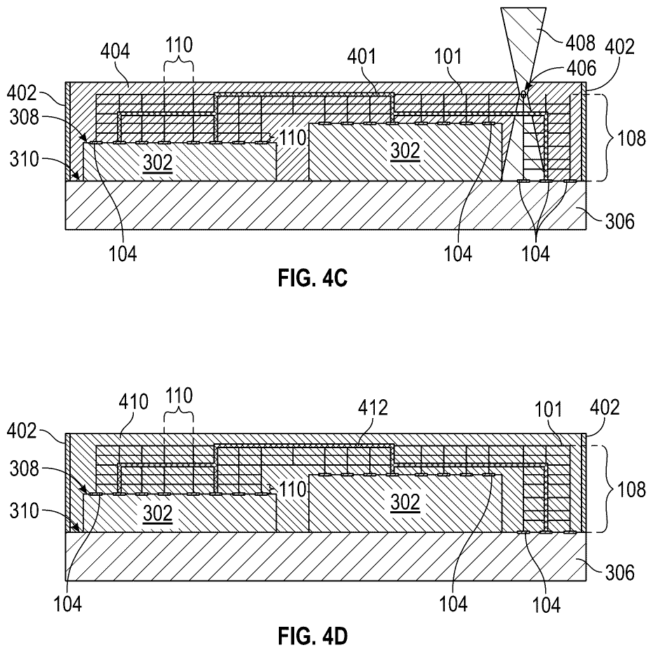

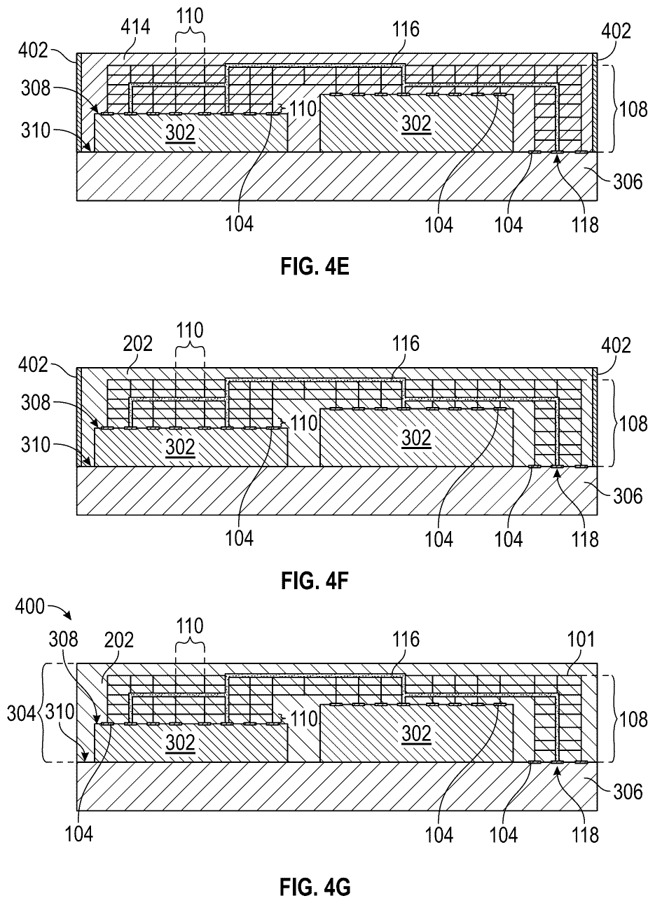

FIG. 1B shows the formation of a lattice structure 108 over the surface 102, the process of which is described herein (e.g., FIGS. 4A-4G). As shown in FIG. 1B, a plurality of struts 110 forms the lattice structure 108. In some embodiments, the struts 110 can form a free-standing wire that extends from conductive contact pad 104 to another conductive contact pad 104. The first layer of struts 110 is formed on the conductive contact pads 104 with a 3D lithography process, and extends vertically (e.g., vertical struts 110a). Horizontal struts 110b are formed similarly with 3D lithography, connecting the vertical struts 110 a to create the lattice framework. The struts 110 comprise a polymer 101. For example, polymer 101 can be a polymerized resin or photoresist. In some cases, the resin can include acrylates, methacrylates, epoxides, fluoropolymers, etc.

A magnified view 112 of a portion of a vertical strut 110a coupled to (e.g., formed on) a conductive contact pad 104 is shown in FIG. 1C. As indicated by the illustration, individual vertical struts 110a that contact the conductive contact pads 104 are formed on the conductive contact pads 104, such that a clearance 114 exists around the base of the vertical strut 110a to later facilitate continuous electrical connectivity between a vertical strut 110a that has been coated with a conductive material and its corresponding conductive contact pad 104. Although not shown, in some cases, more than one strut 110 can contact one conductive contact pad 104. The dimensions of the struts 110 can be defined by multiple parameters of the instrumentation (e.g., wavelength, numerical aperture of the objective lens, intensity, etc. are some of the factors that can affect the size of the smallest volume of polymer formed in a 3D lithographic process (voxel size), and thus affect the dimensions of the smallest feature size that forms the struts). In some cases, the voxel can have a lateral dimension that is in a range between approximately 35 nm and 10 μm, or between approximately 166 nm and 1000 nm, or between approximately 167 nm and 750 nm.

In some cases, the diameter of the vertical strut 110a can correspond to the lateral dimension of the voxel. For example, the diameter of the vertical strut 110a can be approximately 50 nm. In some cases, the diameter of the vertical strut 110 a is between approximately 1% and 99% of the diameter of the conductive contact pads 104, which allows for the existence of a clearance 114.

Portions (or a subset) of the lattice structure 108 can be prepared for a selective process that coats select portions of the lattice structure 108 with a conductive coating 116 (also referred to as a conductive film, or a conductive layer) through electroless plating, electroplating, atomic layer deposition (ALD), sputtering, etc. In some embodiments, the conductive coating 116 can be a metal (e.g., copper (Cu), aluminum (Al), gold (Au) etc.). In some embodiments, the conductive coating 116 can comprise a transparent conductive oxide (TCO) (e.g., indium tin oxide (ITO)). As shown in FIG. 1D, the conductive coating 116 forms an electrical pathway 118 from the conductive contact pad 104 and through the lattice structure 108. The selectivity of the coating process allows for customization and flexibility in the design of the lattice structure 108 to have electrical pathways 118 where desired for various applications, especially in the semiconductor space.

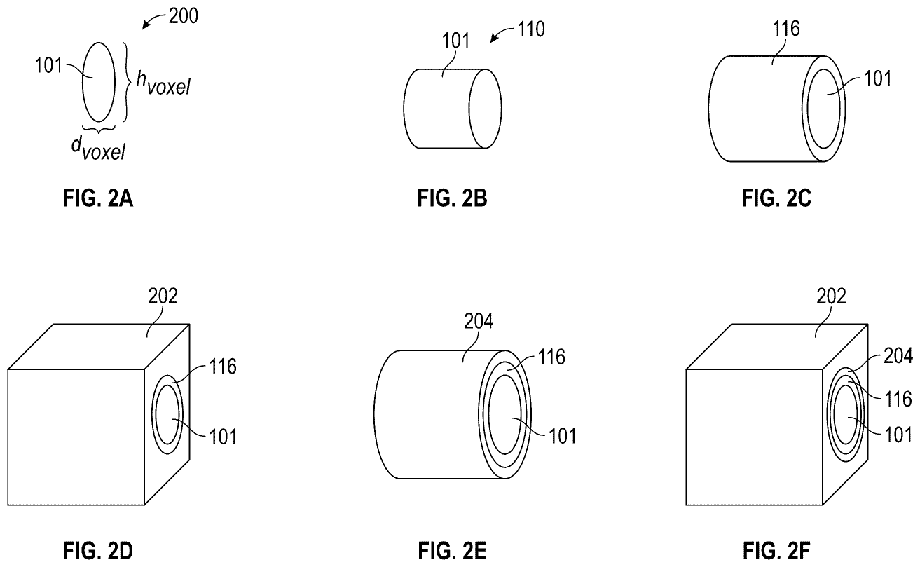

FIGS. 2A-2F are schematic views of a strut 110 at different possible fabrication stages. Unless otherwise noted, components of FIGS. 2A-2F are the same as or generally similar to like-numbered components of FIGS. 1A-1D, and alternatives noted above with respect to FIGS. 1A-1D are likewise applicable to FIGS. 2A-2F. Further, additional details regarding the fabrication process through 3D lithographic selective metallization is described herein with respect to FIGS. 4A-4G.

As shown in FIG. 2A, the basic unit of the strut 110 is the voxel 200, which comprises a polymer. The voxel can have a lateral dimension (e.g., diameter, dᵥₒₓₑₗ) that is in a range between approximately 35 nm and 10 μm, such as between approximately 166 nm and 1000 nm, or between approximately 167 nm and 750 nm and an axial dimension (e.g., height, hᵥₒₓₑₗ). As shown in FIG. 2B, the strut 110 is built from the voxel 200 to achieve a desired length. In some embodiments, the strut 110 may not undergo any selective conductive coating process.

In some embodiments, and as shown in FIG. 2C, the strut 110 can be coated with a conductive coating 116. For example, the conductive coating 116 can be a metal layer having a thickness greater than about 100 nm. In some embodiments, the conductive coating 116 can have a thickness in a range between approximately 100 nm and 30 μm. In some cases, the conductive coating 116 can be completed through techniques based on chemical etching, photolithographic processes, etc. In some cases, the conductive coating 116 can be formed through electroless plating, laser-assisted electroless plating, etc. In some embodiments, the strut 110 corresponds to an at least partially annular conductive wire or an annular conductive wire, where the core comprises the dielectric and the conductive coating 116 is a conductive material at least partially surrounding the dielectric core. In some cases, the at least partially annular wire subtends an angle between approximately 180° and 360° about a central longitudinal axis of the wire. In some cases, the at least partially annular wire subtends an angle of at least 270°, or at least 300°. In some cases, the at least partially annular wire can subtend an angle less than 360° such that it comprises one or more gaps of no conductive material (e.g., not a complete annulus everywhere along the wire), but the wire is electrically continuous, such that it can provide an electrically continuous pathway between a first conductive contact pad 104 and a second conductive contact pad 104. In some embodiments, the strut 110 corresponds to a wire having a closed shape or an at least partially closed shape. For example, in some cases, the wire can have a cross-sectional geometry that is round, ring-like, a ring, polygonal (e.g., rectangular, hexagonal, etc.) etc. In some cases, the strut 110 corresponds to a coaxial wire. In some embodiments, the cross-sectional geometry can comprise a complete annulus. In other embodiments, the cross-sectional geometry can comprise a partial annulus, in which the cross-section may include one or more openings or slots or other discontinuities.

In some cases, following the formation of the conductive coating 116 over the strut 110, the structure can then be encapsulated with a dielectric 202 (also referred to herein as an encapsulant), as shown in in FIG. 2D. In some embodiments, and as shown in FIG. 2E, the coated strut of FIG. 2C can have an insulator coating 204 (e.g., ALD ceramics, etc.) formed over the conductive coating 116. In some cases, one or more barrier material layers can be disposed over the strut 110 (e.g., the coated strut of FIG. 2C) to mitigate electromigration. Like in FIG. 2D, the coated strut of FIG. 2E can be encapsulated with a dielectric 202, as shown in FIG. 2F. In some embodiments, the coated strut 110 can comprise a hollow interior (e.g., if the inner core is developed away or otherwise removed after forming the conductive wire). In some embodiments, the wire can comprise an interior material at least partially surrounded by a coating (e.g., a conductive coating, such as a metallic coating), and the interior material can comprise a solid insulating material (e.g., a polymer), a gas (e.g., air), or a liquid (e.g., a thermal dissipating liquid or dielectric liquid).

FIG. 3 is a schematic cross section of a device package 300 having dies 302 to be electrically connected with an interconnect structure 304 (e.g., mesh interconnect structure). Unless otherwise noted, components of FIG. 3 are the same as or generally similar to like-numbered components of FIGS. 1A-2F, and alternatives noted above with respect to FIGS. 1A-2F are likewise applicable to FIG. 3. In some embodiments, one or more dies 302 (e.g., two or three dies) are disposed on or over a substrate 306. In some cases, the substrate 306 can comprise an organic dielectric. In some cases, the substrate 306 can comprise an inorganic dielectric. In some cases, the substrate 306 comprises silicon. In other cases, the substrate 306 comprises ceramic. The substrate 306 can comprise any suitable type of carrier or substrate, such as a packaging substrate, e.g., a printed circuit board or PCB. In some cases, the substrate is an organic host substrate.

FIG. 3 shows three devices (e.g., three integrated device dies 302a-c) that are coupled to the substrate 306. In some embodiments, a layer of underfill can be included between a die 302 and the substrate 306, with the die 302 being soldered or otherwise bonded to the substrate 306. In some cases, the substrate (or PCB) can comprise wires (e.g., at least partially annular wires) or routing layers that are electrically connected to the dies through one or more vias (e.g., through-substrate vias (TSVs), such as through-silicon vias). In some embodiments, an individual die 302 can comprise a silicon substrate or handle and a silicon active layer disposed over the silicon handle. The silicon active layer can include one or more transistors and routing layers (e.g., Cu BEOL). In some cases, an individual die 302 can have a width between about 1 mm and 3 cm, such as about 5 mm, and a height between about 100 μm and 500 μm, such as 300 μm. In some cases, the dies 302 can be separated from one another such that a die separation distance is between approximately 500 μm and 3 mm, such as 1 mm. A first surface 308 of a die 302 can comprise a plurality of conductive contact pads 104. The size of the substrate 306 can be similar to that of a panel-level packaging substrate. In some cases, the substrate 306 can be approximately 300 mm×300 mm. In some cases, the substrate 306 can have dimensions less than 600 mm×600 mm, such as 100 mm×100 mm, or 150 mm×150 mm, or 200 mm×200 mm. In some embodiments, the substrate 306 can be circular, having diameters such as 100 mm, 150 mm, 200 mm, and 300 mm. The substrate 306 can also comprise a plurality of conductive contact pads 104 at a first surface 310. In some embodiments, the conductive contact pads 104 can comprise an electrically conductive material. In some cases, the conductive contact pads 104 comprise a metal, such as copper or aluminum.

As shown in FIG. 3, the interconnect structure 304 can be formed directly onto the dies 302 in an in situ process. In some cases, the interconnect structure 304 can have a width or depth in a range between about 1 cm and 10 cm, such as 5 cm, and it can have a height between about 200 μm and 2 cm, such as 1 mm. In such an embodiment, processing temperatures can be approximately less than 175° C. to mitigate thermal stresses and possible damage to any integrated circuits or other temperature-sensitive packaging components. The interconnect structure 304 comprises a scaffold that is a mesh or a lattice structure 108 embedded in a bulk material that is a dielectric 202. As described herein, following the fabrication of the lattice structure 108, the lattice structure 108 is encapsulated by a flowable dielectric 202. Because the deposition of the flowable dielectric 202 imparts drag forces on the lattice structure 108, which can impact the integrity of the structure, considerations can be made to incorporate a flowable dielectric 202 having a viscosity between approximately 10 cP and 10,000 cP, such as about 10 cP. In some embodiments, the flowable dielectric 202 can include materials that are different than the photoresist or photosensitive resin, which forms the struts 110. In some embodiments, the flowable dielectric 202 can include polyhedral oligomeric silsesquioxane (POSS), resin derived from B-staged bisbenzocyclobutene (BCB) monomers, polyphenylene ether (PPE)-copolymer-based photo-dielectric, polyimide, parylene, fluorocarbon-based fluids, etc. Some flowable dielectric materials may result in longer fabrication times, but beneficially mitigate the drag forces on the lattice structure 108. Following the deposition of the flowable dielectric 202, the dielectric can be cured.

A plurality of struts 110 form the lattice structure 108. The struts 110 comprise a polymer. For example, the struts 110 can comprise a polymerized resin or a polymerized photoresist as a result of a lithographic process. In some embodiments, and as shown in FIG. 3, the lattice structure 108 can be rectilinear. In some embodiments the lattice structure 108 may not be rectilinear. For example, a portion of the lattice structure 108 can comprise a curvature that can arise when connecting a portion of the lattice structure 108 to conductive contact pads 104. The curvature can arise as a result of a deformation (e.g., bending) in the lattice structure 108. In some embodiments, the lattice structure 108 comprises a repeating unit cell having a unit cell topology of at least one of a simple cubic, a body-centered cubic, a face-centered cubic, a kelvin cell, a diamond, a cubic-diamond, a tetrahedron, an octahedron, an octet-truss, etc.

The struts 110 that form the lattice structure 108 may be referred to as structural wires. The lattice structure 108 of the interconnect structure 304 can comprise approximately 100 layers of the structural wires. In some embodiments, the bottommost layer of struts 110 (e.g., the first layer of struts, which is in contact with the conductive contact pads 104) can have a vertical pitch less than about 235 μm. In some cases, the vertical pitch for the bottommost layer of struts 110 can be between approximately 0.5 μm and 10 mm, such as 2 μm. The vertical pitch can be determined based on considerations of buckling issues that can arise as a result of the weight of the overlying layers of struts 110. In some embodiments, the lateral pitch of the struts 110 for the bottommost layer can be between approximately 0.5 μm and 10 mm, such as 1 μm.

Layers of struts higher up in the interconnect structure 304 can have larger vertical pitches because the weight of the overlying layers is reduced. In some embodiments, the uppermost layer of struts 110 (e.g., the nth layer of struts, such as the one hundredth layer, which has no overlying layer of struts), can have a vertical pitch between about 0.5 μm and 10 mm. In some embodiments, the lateral pitch of the struts 110 for the uppermost layer of struts 110 can be between approximately 0.5 μm and 600 mm. In some embodiments, the struts 110 can have dimensions defined by multiple parameters of the instrumentation used for fabrication (e.g., wavelength, numerical aperture of the objective lens, intensity, etc. are some of the factors that can affect the voxel size of a lithographic process and thus affect the dimensions of the struts). The strut shape can depend on the focal spot size of the light source used in a lithographic process to form the polymeric struts. In some cases, the diameter of a strut 110 can correspond to a lateral (e.g., xy) dimension of a voxel. For example, the diameter of a strut 110 can be approximately 500 nm. In some cases, the length of the strut can correspond to an axial (e.g., z) dimension of a voxel. For example, the length of a strut 110 can be approximately 1 μm.

The lattice structure 108 couples to and extends from the conductive contact pads 104 on each of the dies 302, and portions of the lattice structure 108 are subsequently coated with a conductive coating 116 to form an electrical pathway 118. In some embodiments, the electrical pathway 118 corresponds to a wire (e.g., an at least partially annular wire), which can connect two conductive contact pads in a wafer or in a single die, can connect two conductive pads in two adjacent devices or dies, or can connect conductive contact pads of one or more dies 302 to pads on an underlying substrate 306 as illustrated in at least FIG. 3. Such conductive wires can be implemented in a multi-layered component and can facilitate electrical connection across relatively large distances, yielding a versatile component that can also accommodate high bandwidth demands. In some cases, such a wire can connect conductive contact pads within the substrate, or can facilitate connecting through-substrate vias (TSVs) within the substrate to a routing layer (e.g., RDL). In some embodiments, the electrical pathway 118 can electrically connect two or more devices or dies 302. In some embodiments, the electrical pathway 118 can facilitate the transmission of a signal between two or more devices or dies 302. In some embodiments, the electrical pathway 118 can provide power and/or ground delivery. In some embodiments, the wire can be an at least partially conductive wire that connects to a first contact pad and a second contact pad at respective non-zero angles relative to the first and second contact surfaces of the contact pads. In such cases, the at least partially conductive wire can be continuous and seamless along a length of the wire between the first and the second contact pads. In some embodiments, one or more passive devices or components can be formed along the length of the wire (e.g., one or more capacitors, inductors, etc., which can be in line with the wire).

In some embodiments, the wire can electrically connect a first contact pad 104 at a first surface or a first side of the substrate 306 with a second contact pad 104. The second contact pad 104 can be disposed at the first surface or the first side of the substrate 306, a second surface or side opposite the first surface or side of the substrate 306, or an exterior surface of the device package 306. In some cases, due to the plating process for the conductive coating, the at least partially annular wire extends continuously along its length between the first contact pad and the second contact pad, such that the wire can be considered continuous or seamless along its length. In some cases, the wire can include interfaces only at the point of contact with the first and/or the second contact pads, unlike conventional redistribution layers (RDLs) in which interconnected vias and traces are formed in multiple deposited layers with interfaces therebetween.

In some cases, a first contact pad can be disposed at a first surface of an element (e.g., carrier or substrate), such that the wire extends from the first contact pad in a direction non-parallel to the first surface and connects to a second contact pad. In some cases, the wire extends vertically or is angled relative to a surface of the element (e.g., carrier or substrate), extends horizontally across to a position over a second contact pad, and extends vertically or is angled downwardly to the second contact pad. For example, as shown in FIG. 3, the at least partially annular wire extends vertically from the first contact pad (e.g., non-parallel to the first contact pad or the element in which the first contact pad is formed), vertically from the second contact pad (e.g., non-parallel to the second contact pad or the element in which the second contact pad is formed).

In the illustrated embodiments, the at least partially annular wire can comprise an interior or core material that is an insulator. In various embodiments, the wire can comprise an interior material at least partially surrounded by a coating (e.g., a conductive coating, such as a metallic coating), and the interior material can comprise a solid insulating material (e.g., a polymer), or a fluid (such as a gas (e.g., air), or a liquid (e.g., a thermal dissipating liquid)). for example, in some embodiments, the wire can comprise an interior or core material that is a polymerized photoresist or polymerized photosensitive resin or polymer. In some embodiments, the wire can comprise a hollow interior (e.g., if the inner core is developed away or otherwise removed after forming the conductive annular wire). In some cases, the conductive coating comprises a conductive material that can include copper (Cu), aluminum (Al), nickel (Ni), gold (Au), etc. In some embodiments, one or more barrier layers can be disposed over the wire. For example, the wire can comprise a polymer core, a first coating comprising a first barrier layer (e.g., Ni, cobalt (Co), ruthenium (Ru) etc.), a second coating comprising an electrically conductive material (e.g., Cu, etc.), and/or a third coating comprising a second barrier layer (e.g., Ni, etc.). In some cases, the wire can be embedded in a dielectric material. In some cases, the wire can be at least partially surrounded by air. In some cases, the wire can be surrounded by a thermal dissipating fluid. In some embodiments, a first die 302a is electrically connected with a second die 302b. In some embodiments, a second die 302b is electrically connected with a third die 302c. In some embodiments, a first die 302a is electrically connected with a third die 302c. In other embodiments, the dies 302a-c are electrically connected to conductive contact pads 104 at the first surface 310 of the substrate 306.

In some embodiments, the substrate 306 can be configured to connect or mount to an external device, such as a system board. In other embodiments, the substrate 306 can be removed from the interconnect structure 304, such that the interconnect structure 304 with dies 302 serves as a reconstituted structure that can be bonded or mounted to another device or substrate. Further, the interconnect structure 304 can be singulated into a plurality of structures by sawing or singulating through the dielectric encapsulant 202 (whether the substrate 306 is attached or removed).

FIGS. 4A-4G are schematic cross sections of a process of forming a device package 400 having a 3D mesh interconnect structure, according to one embodiment. Unless otherwise noted, components of FIGS. 4A-4G are the same as or generally similar to like-numbered components of FIGS. 1A-3, and alternatives noted above with respect to FIGS. 1A-3 are likewise applicable to FIGS. 4A-4G.

FIG. 4A shows an example system over which the mesh interconnect structure 340 is fabricated. In FIG. 4A, a substrate 306 having devices 302 coupled to the first surface 310 of the substrate 306 is provided. The substrate 306 can be less than 300 mm in size. The dies 302 can each have a plurality of conductive contact pads 104 at a first surface 308 of the dies 302. In some cases, the pitch of the conductive contact pads 104 can be approximately less than 2 μm. The conductive contact pads 104 can provide starting points for building the mesh interconnect structure 340. In some cases, and as illustrated, the conductive contact pads 104 can also be disposed at the first surface 310 of the substrate 306 to facilitate electrically connecting a die 302 with the substrate 306. Prior to forming the mesh interconnect structure, the substrate 306 and dies 302 are cleaned.

Because the fabrication process entails polymerizing a photoresist, which is a liquid, a containment element 402, such as a jig or similar, is provided over the substrate 306 and surrounds the dies 302, as shown in FIG. 4B. A photoresist 404 (or photosensitive resin) is then deposited over the dies 302 and substrate 306, filling the containment element 402. In some cases, the photoresist 404 can include an acrylate, a methacrylate, epoxides, fluoropolymers, etc. Then, a lithographic process, such as microstereolithography or multi-photon lithography, is implemented to polymerize select regions of the photoresist to form the lattice structure 108 comprising struts 110 as shown in FIG. 4C. In some embodiments, the fabrication process can include implementing a photoresist that is a precursor for an inorganic dielectric, such that when it is cured, no trace remains of the original photoresist material.

In FIG. 4C, a 3D lithographic process like microstereolithography and two-photon lithography can be used to polymerize or locally solidify the resin (e.g., photosensitive resin) or photoresist. Using the nonlinear optical absorption phenomena of two-photon absorption, the resin is polymerized within a laser focal spot 406. In some cases, the structure formed from the lithographic process can be periodic. In some cases, the structure can be non-periodic. FIG. 4C indicates that light 408 from a source (not shown) having a focal spot 406 can be projected, or scanned to form polymer 101. At least a portion of the polymer 101 of the lattice structure 108 will be prepared for selective conductive coating, as indicated by the trace 401. For example, the parameters of the incident beam can be adjusted to prepare portions of the lattice structure 108 for selective coating. In some embodiments, the intensity at the focal spot 406 can be changed to facilitate defining the regions to be coated with a conductive coating or layer as compared to regions that are not to be coated with the conductive layer. In some embodiments, multiple photoresists can be implemented to facilitate preparing portions (e.g., preparing surfaces, or activating surfaces) of the lattice structure 108 for selective coating. In some embodiments, other techniques as may be known by those skilled in the art can be employed to alter the cross-linking density or the surface reactants so as to prepare select regions for deposition of a conductive coating, while leaving other regions uncoated with the conductive material. In some embodiments, processes like orthogonal polymerization (which uses different wavelengths of light), laser-direct structuring, and any other suitable techniques known in the art can be implemented to facilitate selective coating. It should be appreciated by those skilled in the art, that the coating can be non-selective such that all of a formed lattice structure or wire could be coated (e.g., metallized).

In FIG. 4D, the photoresist that has not been polymerized is removed. In some embodiments (not shown), the polymerized photoresist could be removed instead. In some embodiments, and as shown in FIG. 4D, an electroless plating solution 410 can be provided over the lattice structure 108 and a seed layer 412 formed over the trace 401. In some cases, the seed layer 412 comprises at least one of nickel (Ni) or a Ni alloy, palladium (Pd), palladium-tin colloids, copper, cobalt, chromium, etc. In some cases, the seed layer is approximately 200 nm. In some embodiments, the material for the seed layer 412 is selected to minimize or to not result in forming low conductivity intermetallics at equilibrium conditions with materials to be implemented as the conductive coating, such as Cu, Au, Al, etc.

Following formation of the seed layer 412, the electroless plating solution can be removed, and as shown in FIG. 4E, the containment element 402 can be filled with an electroplating solution 414. A conductive coating 116 like a Cu layer can be formed over the seed layer 412. The portions of the struts 110 of the lattice structure 108 coated with the conductive coating 116 can have an overall diameter in a range between 600 nm and 40 μm. In some embodiments, the interior polymer 101 can be removed, leaving behind the conductive coating 116. In some cases, the interior polymer 101 can be removed with an isotropic wet etch, or isotropic plasma descum etch. In such cases, the remaining conductive coating 116 includes one or more holes to allow the decomposition byproducts to escape from inside of the wire. After the selective coating (e.g., selective metallization) of the lattice structure 108, the electroplating solution can be removed and replaced with a flowable dielectric 202, as shown in FIG. 4F. The flowable dielectric 202 can comprise materials like polyhedral oligomeric silsesquioxane (POSS), resin derived from B-staged bisbenzocyclobutene (BCB) monomers, polyphenylene ether (PPE)-copolymer-based photo-dielectric, polyimide, parylene, fluorocarbon-based fluids, etc. In some embodiments, the flowable dielectric 202 is selected to have a low viscosity, to mitigate the effect of drag forces on the lattice structure 108. For example, the flowable dielectric 202 can have a viscosity in a range between approximately 10 cP and 10,000 cP. After the flowable dielectric 202 is deposited, it can be cured as shown in FIG. 4G. The containment element 402 can also be removed. In some cases, the dielectric or encapsulant can be a foam (e.g., a foam with voids of air or other inert gases with low loss tangents).

In some embodiments, the fabrication process can be similar to a process like laser direct structuring. The fabrication process starts in a similar manner as the process shown in FIGS. 4A-4B. Instead of forming the trace 401 as shown in FIG. 4C, the lattice structure 108 is completed without the trace 401. Then, the photoresist can be removed and replaced with a precursor photoresist. A laser is used to form a precursor polymer along portions of the lattice structure 108 to be coated with a conductive material. After forming the precursor polymer, the precursor photoresist is removed and replaced with a plating solution to facilitate the selective metallization. For example, a Cu layer is formed to conformally coat the formed precursor polymer. Then, the plating solution is removed and replaced with a flowable dielectric, which is then cured to obtain the final product. In some embodiments, after curing the flowable dielectric, the package can be diced or singulated to form individual packages.

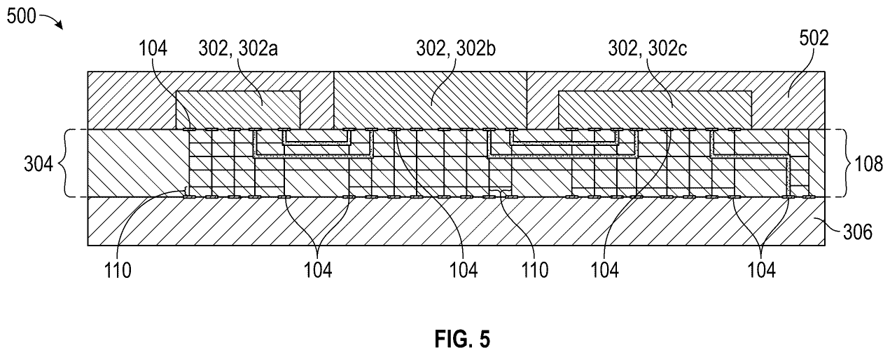

FIG. 5 is a schematic cross section of a device package 500 having three dies 302 to be electrically connected with a 3D mesh interconnect structure, according to another embodiment. Unless otherwise noted, components of FIG. 5 are the same as or generally similar to like-numbered components of FIGS. 1A-4G, and alternatives noted above with respect to FIGS. 1A-4G are likewise applicable to FIG. 5. Unlike in the earlier described embodiments, the embodiment of FIG. 5 shows a package where the interconnect structure 304 comprising the lattice structure 108 is fabricated over a carrier element or a substrate 306 prior to die attachment. In some embodiments, the dies 302 can be aligned and attached to the interconnect structure 304 through any suitable bonding process as known by those skilled in the art in a die-last assembly. Then, an encapsulant 502 can be provided to encapsulate the dies 302. In some embodiments, the fabrication process can proceed in a die-first assembly, where the interconnect structure 304 is fabricated over the dies 302 and the substrate can subsequently be formed over the interconnect structure 304. FIG. 5 shows that first die 302a can be electrically connected with the second die 302b; that the second die 302b can be electrically connected with the third die 302c; and that the third die 302c can be electrically connected to the conductive contact pads 104 on the substrate 306. Because of the flexible programmability of the fabrication process regarding both the formation of the lattice structure 108 and the selective metallization, many electrical pathway configurations can be designed and formed.

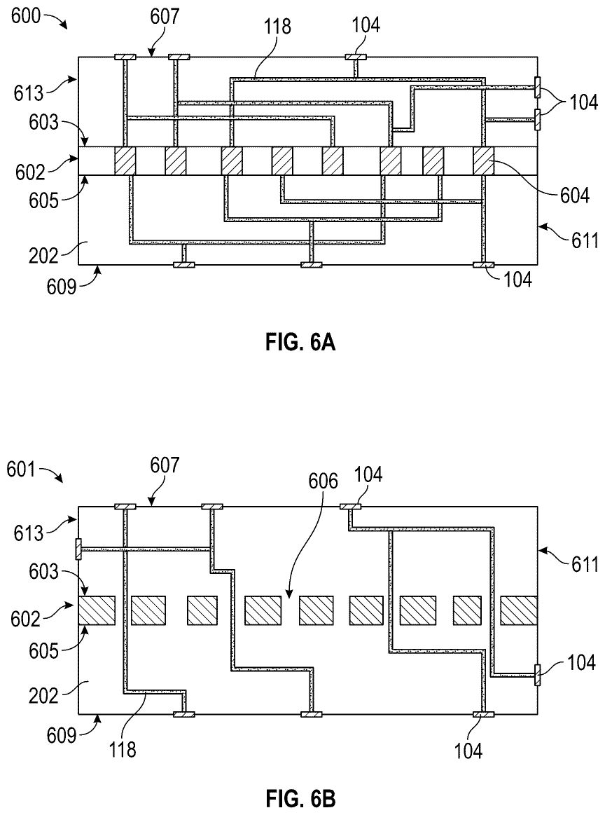

FIGS. 6A-6B are schematic cross sections of an interconnect structure 600, 601 having a core substrate 602. Unless otherwise noted, components of FIGS. 6A-6B are the same as or generally similar to like-numbered components of FIGS. 1A-5, and alternatives noted above with respect to FIGS. 1A-5 are likewise applicable to FIGS. 6A-6B. In some embodiments, the interconnect structure can be two-sided, such that the interconnect structure comprises a core substrate with lattice structures that can be formed over a first side 603 and a second side 605 of the core substrate. One example is illustrated in FIG. 6A where the interconnect structure 600 has a core substrate 602 that is similar to the substrate 306 described herein. In some cases, the core substrate 602 can comprise silicon, glass, ceramic, or an organic dielectric. In FIG. 6A, the core substrate 602 can comprise a plurality of through-substrate vias 604, which can facilitate electrical connections across (or through) the core substrate 602 and between the wires or electrical pathways 118 that can be formed on either side 603, 605 of the core substrate 602. A plurality of conductive contact pads 104 can be provided on a first side 607 or upper surface and/or a second side 608 or bottom surface of the interconnect structure 600. In some cases, the conductive contact pads 104 can also be incorporated on a sidewall 611, 613 (e.g., a side of the interconnect structure corresponding to the dielectric 202 portions that is approximately orthogonal to the first and second sides 607, 609) of the structure 600 (e.g., along an outer surface of the dielectric encapsulant 202, such that the electrical pathway extends between the substrate and the outer surface of the encapsulant 202). Sidewall 611 is opposite sidewall 613. Placement of conductive contact pads 104 on a sidewall 611, 613 of structure 600 can beneficially allow electrical coupling between the interconnect structure 600 and a device (e.g., a die or a chip) that is adjacent to the sidewall 611, 613. In some cases, the conductive contact pads 104 can be placed on a top surface, a bottom surface, or any other surface of the interconnect structure. In some cases, the electrical pathway 118 can extend between two conductive contact pads, where the two conductive contact pads can be disposed substantially anywhere in the interconnect structure 600. In some cases, the interconnect structure 600 can be fabricated using a process like the process described with respect to at least FIGS. 4A-4G.

FIG. 6B shows an interconnect structure 601 similar to that of FIG. 6A. In FIG. 6B, the core substrate 602 is transparent (optically transparent, such as glass) and index-matched, which enables patterning on both sides 603 and 605. In some embodiments, the core substrate 602 is optically transparent to wavelengths in a range of wavelengths corresponding to visible light, or in a range of wavelengths corresponding to infrared light, or in a range of wavelengths corresponding to ultraviolet light. For example, the core substrate 602 can be optically transparent to wavelengths of between about 180 nm and 1500 nm. As shown in FIG. 6B, the core substrate 602 includes a plurality of holes (e.g., through-holes 606), which provides an opening for the wires or electrical pathway 118 to traverse. For example, the through-holes 606 allow for electrical connections between the conductive contact pads 104 on one side 607 of the interconnect structure 601 and the conductive contact pads 104 on an opposing side 609 of the same interconnect structure 601. In some cases, the interconnect structure 601 can be fabricated using a process like the process described with respect to at least FIGS. 4A-4G. Beneficially, with the index-matched and optically transparent core substrate 602 in FIG. 6B, the fabrication process can be simplified in allowing for patterning over both sides 603, 605 of the core substrate 602 at about the same time (as opposed to the fabrication process for the interconnect structure 600, which would likely proceed in a sequential manner (e.g., patterning one side at a time)).

In some embodiments, the interconnect structure can be fabricated and then subsequently attached or coupled to other elements. For example, in some cases, the interconnect structure can include an at least partially annular conductive wire that is disposed about an insulator or a dielectric (e.g., a dielectric core), and the ends of the at least partially annular conductive wire are configured to connect to one or more conductive contact pads (or contact pads), where the one or more conductive contact pads can be disposed on or embedded in some element, such as a substrate, a carrier element, a die, etc. The ends of the at least partially annular conductive wire can be attached or coupled to one or more contact pads. In some cases, the wire ends can be bonded to one or more contact pads, or attached with solder to one or more contact pads, or attached with any other suitable attachment or bonding method. In some embodiments, the interconnect structure can be fabricated and then subsequently attached to other elements. In some cases, the interconnect structure can be similar to or the same as the interconnect structures described herein.

In any of the embodiments described herein, e.g., FIGS. 1A-6B, the lattice structure 108 (or a wire) can be encapsulated in a solid dielectric, such as the flowable dielectric 202 that is cured to form a solid or semi-solid. In some cases, also applicable to the embodiments described herein and shown in FIGS. 1A-6B, the lattice structure 108 (or a wire) can be disposed in a fluid (e.g., a gas such as air, or in a liquid (e.g., a liquid-filled lattice, where the liquid can include a dielectric liquid)). For example, the interconnect structures 600, 601 of FIG. 6A and FIG. 6B, respectively, can include a (patterned) dielectric coating having conductive contact pads or terminals on the outside of the dielectric coating, which effectively seals off the interconnect structure 600, 601 from outside environs. In some embodiments, the interior of the interconnect structure 600, 601, can comprise a lattice structure (or plurality of wires or electrical pathways) disposed in a gas (e.g., air) or a liquid (e.g., dielectric liquid), with the gas or liquid sealed by the exterior coating applied over the outer surface of the interconnect structure 600, 601. Referring to FIGS. 6A-6B, the solid dielectric coating that effectively encapsulates and seals off the interior of the interconnect structure from the outer environs can be disposed at surfaces corresponding to or external to the sides labeled 607, 609, 611, and 613.

A device package fabricated with an additive manufacturing process is described. Such fabrication processes include microstereolithography, multi-photon lithography (e.g., one-plus-one photon lithography, two-photon lithography), which utilizes absorption properties such that photosensitive resin can be converted into polymer within the focal plane or focal spot of a rastering image or beam. The device package can include a substrate with dies or devices attached to a surface of the substrate. Using a lithographic process, a lattice structure comprising a plurality of polymeric struts can be formed directly onto the dies or devices to be electrically connected. Further, the lithographic process can implement selective metallization of the lattice structure to provide electrical pathways where desired. Thus, a programmable fabrication process can enable the creation of a 3D mesh interconnect structure that is highly customizable, and which can facilitate electrical connections between devices having high density electrical contacts.

The 3D mesh interconnect structure (e.g., high-bandwidth 3D mesh interposer) transcends the two-dimensional constraints of traditional interposers. The interconnect structure can have higher layer counts and increased interconnect densities, which assist in advanced computing applications. Such structures can meet the bandwidth, efficiency, latency, and cost needs in the semiconductor industry and other related industries. Chip design can be simplified by enabling high bandwidth, native chip speed signaling, and with the ability to carry out in situ fabrication over entire wafers, mechanical bonding pitch limitations can be eliminated (e.g., the interconnect structures can facilitate wafer-scale at micron contact pitch connections). Additionally, the fabrication processes can include digitized manufacturing to accelerate the design-to-production cycle from months to hours, enabling rapid innovation and adaptation to evolving technological demands. The process is also scalable and flexible, as the same equipment for carrying out the 3D lithography can accommodate both prototyping and high-volume manufacturing, which ensures reliability and successful scale-ups. 3D nanofabrication costs are also reduced, given that with the process described herein, costs scale with the materials, and not the layers (e.g., 3D lithography leverages economies of scale). Notably, high yield, advanced packages can be achieved with greater freedom for fault-tolerant design, real-time tomographic monitoring, autocorrection and redundant wiring, at minimal cost. And, with the described technology, ecosystem integration and system optimization can occur as the design space of connectors and integrated solutions (e.g., by eliminating bonding, geometric, and dimensional constraints) is massively broadened.

The interconnect structure described herein can be fabricated by a maskless, multi-material, 3D lithography process. This process additively produces complex 3D structures directly on chiplets material-by-material, rather than layer-by-layer, which significantly reduces process costs. Beneficially, the fabrication process unlocks a new paradigm in efficient interconnects by increasing metal layer count, instead of data rate. One objective of the described interconnect structure technology is to provide a short distance connector. In some cases, the interconnect structure comprises a transceiver operating at native chip clock speeds, paired with extreme flexibility in metal layer count (from 10 s to 1000 s) at about a 2 μm pitch, making possible efficient ultra-high bandwidth density connectors. In some cases, the additive manufacturing processes can operate at rates greater than 10² mm³/hr to fabricate a cured feature within the uncured (or unpolymerized) resist, which contributes to the formation of a polymer scaffolding at one wavelength of light (e.g., 21). A second wavelength of light (e.g., 22) can facilitate formation of a conductor seed for selective metallization, and copper plating can subsequently occur to form a conductive wire that can be implemented in a variety of applications.

### Example Parameters of the Interconnect Structure

In some embodiments, the interconnect structure can have traces that are between about 0.1 mm and 25 mm. In some cases, traces that are up to 300 mm can be achieved. In some embodiments, the bandwidth of the interconnect structure can be between about 10 Tb/s/mm and 20 Tb/s/mm. In some cases, such an interconnect structure can have approximately 100 layers of metal traces at a 2 μm pitching, running at about 0.5 GHz to 1.0 GHz. In some embodiments, the efficiency of the interconnect structure can be less than about 0.1 pJ/bit. In some cases, a multiplexer/demultiplexer is not needed. In some cases, the structure can have a low swing voltage. In some embodiments, the interconnect structure can have a latency that is between about 0.1 ns and 2 ns. In some embodiments, the latency can be less than 0.1 ns. Notably, there is a simple time closure, and the conductors are high-quality conductors. In some embodiments, the interconnect structure can facilitate speeds between about 0.5 GHz and 1.0 GHz. Running at native close speeds can mean minimizing overhead. In some embodiments, channel IL can be significantly less than 1 dB at 1 GHz, 25 mm. This innovation corresponds to high-quality and tunable material properties. In some embodiments, the bit error rate (BER) can be less that 10-12, as a result of the embedded shielding for minimizing crosstalk in the interconnect structure. In some embodiments, the s-FoM can be about 10⁴¹⁻⁴² (bit/s/m)²/J, where the transceiver area can be scaled to a 5 nm node.

### Example Transceiver Implementation

The interconnect structure and processes described herein minimize the transistor area, J/bit, and latency required to communicate across chiplets by operating at or near native chiplet clock speeds (about 1 GHz). Due to the high channel count and correspondingly lower connector frequency, time closure can be managed with buffers. Input and output to 45 nm CMOS test chips can be provided externally to the wafer-scale connector for test and diagnostic purposes. Power consumption and bit error rates can be analyzed and traded against corresponding die areas to maximize the s-FoM of the system. The transceiver can be designed and fabricated on the 45 nm node to reduce development costs and time with transferability to leading-edge nodes. The proposed wafer-scale system can be compatible with die-to-die interfaces. In some cases, the initial 45 nm CMOS chip will implement wire drivers and receivers that can be incorporated into die-to-die PHY interfaces for future wafer-scale XPU systems. The PHY circuits that drive the wire and receive the signal are estimated to contribute most of the connector power consumption. In some embodiments, the driver can operate with a low swing, in the range of 0.2 V to 0.3 V, to minimize power consumption and operate at a low enough speed in which additional overhead is minimized to overcome high-speed transmission line losses. In some cases, detailed clocking, PLL, and synchronization analysis can be performed to identify optimal data rates. The transceiver can integrated built-in self-test and active link monitoring to achieve signal quality and efficient traffic management across many channels.

### Example Thermomechanical Modeling

To address thermos-mechanical instabilities from coefficient of thermal expansion mismatches, a simulation software can be implemented. For example, an AI-powered physics simulation software that is GPU-accelerated can be used to generate detailed, multi-scale simulations of temperatures and stresses at the wire, via, and transistor levels across entire designs in a relatively short period of time (e.g., minutes) on consumer GPUs. In some cases, the software models can be calibrated using measured thermal and mechanical properties of the interconnect structure components to account for manufacturing variations. In some embodiments, full thermal-mechanical simulations can validate design stability under various operating conditions, and Monte Carlo analyses can identify risks from process-induced variations, supporting high-volume manufacturing readiness.

### Example Materials Engineering and Characterization

In situ fabrication of the interconnect structure directly on chiplets would mean having low process temperatures (e.g., less than 180° C.) to minimize thermal strains and dopant diffusion in substrates and chiplets. Recent advances in low-temperature processes for selective metallization of photopolymers enables the in situ fabrication in some cases. In some cases, to connect less than 2 μm pitch contacts across a 300 mm wafer, would correspond to high aspect ratio (HAR) wires. If left unsupported, such HAR wires can deform, resulting in material failure or short circuits. To mitigate this, in some cases, photopolymerized dielectric scaffoldings can support the metal precursor polymers, which can seed subsequent wire metallization. Multiple approaches can be used to spatially localize metal seed layers by altering the composition of the photoresists. Examples include using bis(2-(methacryloyloxy)ethyl))phosphate (PDD) to produce a charged monomer, chromo-selective orthogonal polymerization using functionalized epoxide and acrylate monomers, nanoparticle catalysts generated by photoreduction reactions, and the addition of metal-containing laser sensitizers. Another approach can include switching different resists between patterning steps. The 3D lithographed catalyst-containing structures can then be electroless plated to obtain highly conductive metal wires to more than 10% bulk conductivity. In some cases, processes implementing multiple separate photoresists can be accelerated by matching the refractive index of dissimilar resins and polymers to allow the laser foci to be localized within an existing structure. Aberrations can be mitigated with spatial light modulators and inverse beam forming. In some cases, material quality and defect types can be rigorously studied to inform system requirements (e.g., EBSD and FIB to assess microstructure, EDS for chemical composition, in addition to nanomechanical tests).

After the pattering of negative-tone photoresists, the mesh of wires that form the interconnect structure are encapsulated in a dielectric. A photo-initiable flowable dielectric, such as polyhedral oligomeric silsesquioxane (POSS), can fill the voids of the mesh. The viscosity can be tailored to minimize viscous drag forces imparted on the structure that can lead to structural failure.

### Example Process Characterization and Scaleup

In some embodiments, the maskless localized photo-polymerization of less than 2 μm pitch, less than 1 μm diameter conductors of up to 100 layers, and up to cm length scales can be achieved with a 3D lithographic process like a microstereolithography (μSL) or multi-photon lithography (MPL) process. μSL uses a continuous-wave (CW) or pulsed ultraviolet (UV) laser to photopolymerize layers of photoresist, producing features typically in the range of 1-50 μm. Resolution is governed by optical diffraction limits, laser spot size, and resin absorption characteristics rather than nonlinear optical effects. MPL uses a high peak power, femtosecond, laser to focus into a photoresist to photopolymerize 3D pixels, or voxels, smaller than the laser wavelength (e.g., 35 nm). The bi-material polymeric approach can be integrated with existing photoresist (e.g., MPL-resist) chemistries. Integrated optical feedback with fiducials can be implemented on the chiplets and package to adapt to misalignments and defects. In some cases, the 3D lithography can produce 1 s to 1000 s of cubic centimeters per hour of nanostructured materials at a wafer scale (e.g., ones to 1000 s of interconnect structure or interposer per couple of hours). In some cases, the MPL can be scaled by 10-100 times to produce many interposers per hour. In some cases, the 3D lithography can be coupled with generative design and in situ testing, allowing for rapid prototyping and scalability for high-volume production. In some cases, focus can be placed on maximizing yield by characterizing and mitigating defects. Design for Manufacturing (DFM) rules can be defined. Built-in computer vision and digital twins using machine learning can be implemented to learn and correct errors. In some cases, redundancy in wire paths can square yield. In some cases, redundancy in wire paths can power-law increase yield. In some cases, the interconnect structure can be continuously optimized for reliability by parallelizing generative design, fabrication, and testing of packages, eliminating design cycles. In some cases, and at various phases, process efficiency can be assessed through Operation Readiness Tests, where the production process can be run over representative periods to ensure consistent output. Multiple comprehensive test campaigns of the interconnect structure described herein can be conducted, following industry-standard practices to validate product reliability. For example, destructive tests covering electrical, thermo-mechanical, reliability, environmental, and accelerated lifetime assessments can be completed. In some cases, the 3D lithographic process implemented can enable test-specific articles to be rapidly fabricated. The testing procedures can comply with relevant standards such as JEP132A, JEP70C, JEP001A, JEP156, and industry standard guidelines.

### Example Mesh Interconnect Structure or Interposer Dimensions

In some embodiments, an interconnect structure or interposer, such as one described herein (e.g., FIGS. 3-5) can have various parameters. For example, the structural wires of the interconnect structure can have a vertical pitch between approximately 0.9 μm and 1.1 μm, such as 1 μm, and a lateral pitch between approximately 0.9 μm and 1.1 μm, such as 1 μm. In some cases, a diameter of one of these structural wires can be between 240 nm and 260 nm, such as 250 nm, and the fractional metallized (e.g., Cu) area can be between about 0.5 and 0.8, such as 0.8. In some cases, the wire resistance can be between about 0.70 and 0.44 ohm/μm, such as about 0.54 μm. In some cases, the maximum DC current can be between approximately 122 μA and 196 μA, such as 160 μA (100 C, 100 khr). In some cases, the density of wiring as compared to the maximum possible density is between about 75% and 100%, such as 90%. In some embodiments, the distance to surface for a wire (structural wire) that touches the surface for a fill can be between 0 mm and 5 mm. In some cases, the defectivity rate (e.g., random chance for a wire to break in 1 cm length) can be about 1e-9. In some embodiments, the dielectric constant for the interconnect structure background is about 4. In some embodiments, the capacitance per unit length for a single wire can be about 100 aF/μm. In some embodiments, the rise time for signal propagation can be about 54 ps/mm².

### Example Technical Significance

The interconnect structure described herein can provide improvements in advanced packaging. Significant and achievable technical advances can be made with a high bandwidth, low power interposer. In situ additive manufacturing of such interposers can open up the design space, greatly increasing the rate of innovation of high-performance connectors. The 3D lithographic process enables contact pitch of less than 2 μm and over 300 mm wafer-scale packages. High-quality conductor material properties maintain efficiency. An 3D lithographic process that can be implemented is a maskless, high-resolution process that can actively adapt to chiplet contact size, height, and arrangement. The interconnect structure (or interposer) can operate at near native chip data rates, minimizing transceiver overhead. Additionally, the maskless fabrication process is scalable from prototyping to high-volume manufacturing use the same tools, accelerating time to market. Iterating connectors will not be limited by manufacturing, as an interconnect structure like an interposer can be manufactured in minutes to hours, which can aid AI and HPC. Finally, research and development (R&D) efforts can be aligned for implementable packaging flows. For example, work can be done with various R&D areas to integrate new materials and substrates, close the loop with DFM with co-design/electronic design automation, integration with new equipment, tools, processes, and process integration, and develop and validate digital twins for power delivery and thermal management. An operando testing suite can enable leverage to accelerate design for chiplet ecosystems.

In some aspects, an interconnect structure is disclosed. The interconnect structure can comprise an at least partially annular conductive wire that is disposed about an insulator. The ends of the at least partially annular conductive wire are configured to connect to one or more conductive contact pads (or contact pads), where the one or more conductive contact pads can be disposed on or embedded in some element, such as a substrate, a carrier element, dies, etc. The ends of the at least partially annular conductive wire can be attached to or coupled to one or more contact pads. In some cases, the wire ends can be bonded to one or more contact pads with any suitable attachment or bonding method. In some embodiments, the interconnect structure can be fabricated and then subsequently attached to other elements.

In some aspects, the techniques described herein relate to a device package including: an interconnect structure including an at least partially annular conductive wire disposed about an insulator; a first contact pad at a first surface of an element, wherein the wire extends from the first contact pad in a direction non-parallel to the first surface and connects to a second contact pad.

In some embodiments, the techniques described herein relate to a device package, wherein the interconnect structure includes a solid dielectric material in which the wire is encapsulated.

In some embodiments, the techniques described herein relate to a device package, wherein the wire is disposed in a fluid.

In some embodiments, the techniques described herein relate to a device package, further including a dielectric coating on an outer surface of the interconnect structure to seal the interconnect structure.

In some embodiments, the techniques described herein relate to a device package, wherein the insulator includes a polymer material, the wire including a coating disposed about the polymer material.

In some embodiments, the techniques described herein relate to a device package, wherein the coating includes a conductive material.

In some embodiments, the techniques described herein relate to a device package, wherein the polymer material includes a polymerized photoresist.

In some embodiments, the techniques described herein relate to a device package, wherein the coating includes a conductive material, and wherein a second coating is disposed adjacent to the coating, wherein the second coating includes a barrier layer.

In some embodiments, the techniques described herein relate to a device package, wherein the insulator is at least one of solid insulating material, a gas, or a liquid.

In some embodiments, the techniques described herein relate to a device package, wherein the element includes a first device die.

In some embodiments, the techniques described herein relate to a device package, further including a second device die that includes the second contact pad.

In some embodiments, the techniques described herein relate to a device package, further including a substrate, the first device die and the second device die mounted to the substrate.

In some embodiments, the techniques described herein relate to a device package, further including a dielectric encapsulant in which the wire and the first and second device dies are at least partially embedded.

In some embodiments, the techniques described herein relate to a device package, wherein the element includes a substrate.

In some embodiments, the techniques described herein relate to a device package, wherein substrate includes the second contact pad.

In some embodiments, the techniques described herein relate to a device package, further including a first dielectric material on a first side of the substrate, the wire at least partially embedded in the first dielectric material.

In some embodiments, the techniques described herein relate to a device package, wherein the second contact pad is disposed at an outer surface of the first dielectric material.

In some embodiments, the techniques described herein relate to a device package, further including a second dielectric material on a second side of the substrate opposite the first side.

In some embodiments, the techniques described herein relate to a device package, wherein the substrate includes a transparent substrate and the wire extends through the substrate.

In some embodiments, the techniques described herein relate to a device package, wherein the at least partially annular conductive wire is continuous and seamless along a length between the first and second pads.

In some embodiments, the techniques described herein relate to a device package, wherein the interconnect structure includes a plurality of at least partially annular conductive wires including the at least partially annular conductive wire, each wire of the plurality of at least partially annular conductive wires extending between and connecting at least two contact pads.

In some embodiments, the techniques described herein relate to a device package, wherein the interconnect structure includes a scaffold including a plurality of struts, the plurality of at least partially annular conductive wires formed of the plurality of struts.

In some embodiments, the techniques described herein relate to a device package, wherein a first subset of struts includes at least one dielectric material and a conductive coating disposed at least partially about the at least one dielectric material, the plurality of at least partially annular conductive wires including the conductive coating.

In some embodiments, the techniques described herein relate to a device package, wherein a second subset of struts includes the at least one dielectric material without the conductive coating.

In some aspects, the techniques described herein relate to a device package including: at least one element including a first contact pad having a first contact surface and a second contact pad having a second contact surface; an interconnect structure including an at least partially annular conductive wire disposed about an insulator, the at least partially annular conductive wire extending between and electrically connecting the first and second contact pads, wherein the at least partially annular conductive wire connects to the first and second contact pads at respective non-zero angles relative to the first and second contact surfaces, and wherein the at least partially annular conductive wire is continuous and seamless along a length between the first and second contact pads.

In some embodiments, the techniques described herein relate to a device package, wherein the interconnect structure includes a solid dielectric material in which the wire is encapsulated.

In some embodiments, the techniques described herein relate to a device package, wherein the wire is disposed in a fluid.

In some embodiments, the techniques described herein relate to a device package, further including a dielectric coating on an outer surface of the interconnect structure to seal the interconnect structure.

In some embodiments, the techniques described herein relate to a device package, wherein the insulator includes a polymer material, the wire including a coating disposed about the polymer material.

In some embodiments, the techniques described herein relate to a device package, wherein the coating includes a conductive material.

In some embodiments, the techniques described herein relate to a device package, wherein the polymer material includes a polymerized photoresist.

In some embodiments, the techniques described herein relate to a device package, wherein the coating includes a conductive material, and wherein a second coating is disposed adjacent to the coating, wherein the second coating includes a barrier layer.

In some embodiments, the techniques described herein relate to a device package, wherein the insulator is at least one of solid insulating material, a gas, or a liquid.

In some embodiments, the techniques described herein relate to a device package, wherein the element includes a first device die.

In some embodiments, the techniques described herein relate to a device package, further including a second device die that includes the second contact pad.

In some embodiments, the techniques described herein relate to a device package, further including a substrate, the first device die and the second device die mounted to the substrate.

In some embodiments, the techniques described herein relate to a device package, further including a dielectric encapsulant in which the wire and the first and second device dies are at least partially embedded.

In some embodiments, the techniques described herein relate to a device package, wherein the element includes a substrate.

In some embodiments, the techniques described herein relate to a device package, wherein substrate includes the second contact pad.

In some embodiments, the techniques described herein relate to a device package, further including a first dielectric material on a first side of the substrate, the wire at least partially embedded in the first dielectric material.

In some embodiments, the techniques described herein relate to a device package, wherein the second contact pad is disposed at an outer surface of the first dielectric material.

In some embodiments, the techniques described herein relate to a device package, further including a second dielectric material on a second side of the substrate opposite the first side.

In some embodiments, the techniques described herein relate to a device package, wherein the substrate includes a transparent substrate and the wire extends through the substrate.

In some embodiments, the techniques described herein relate to a device package, wherein the at least partially annular conductive wire is continuous and seamless along a length between the first and second pads.

In some embodiments, the techniques described herein relate to a device package, wherein the interconnect structure includes a plurality of at least partially annular conductive wires including the at least partially annular conductive wire, each wire of the plurality of at least partially annular conductive wires extending between and connecting at least two contact pads.

In some embodiments, the techniques described herein relate to a device package, wherein the interconnect structure includes a scaffold including a plurality of struts, the plurality of at least partially annular conductive wires formed of the plurality of struts.

In some embodiments, the techniques described herein relate to a device package, wherein a first subset of struts includes at least one dielectric material and a conductive coating disposed at least partially about the at least one dielectric material, the plurality of at least partially annular conductive wires including the conductive coating.

In some embodiments, the techniques described herein relate to a device package, wherein a second subset of struts includes the at least one dielectric material without the conductive coating.

In some aspects, the techniques described herein relate to a device package including: an interconnect structure including a scaffold, wherein the scaffold includes an uncoated dielectric structure and a coated polymer structure, wherein the coated polymer structure includes a first coating, the coated polymer structure to provide a plurality of electrical pathways including a first electrical pathway; and at least one element including a first contact pad and a second contact pad, wherein the interconnect structure electrically connects the first contact pad with the second contact pad through at least the first electrical pathway.

In some embodiments, the techniques described herein relate to a device package, wherein the first coating includes a conductive material.

In some embodiments, the techniques described herein relate to a device package, wherein the conductive material includes copper, aluminum, nickel, or gold.

In some embodiments, the techniques described herein relate to a device package, further including a second coating disposed over the first coating, wherein the second coating includes an insulator.

In some embodiments, the techniques described herein relate to a device package, wherein the first coating includes an at least partially annular wire.

In some embodiments, the techniques described herein relate to a device package, wherein the at least partially annular wire includes a complete annulus.

In some embodiments, the techniques described herein relate to a device package, wherein the at least partially annular wire includes a first portion extending non-parallel to the first contact pad, a second portion extending non-parallel to the second contact pad, and a third portion between the first and second portions.

In some embodiments, the techniques described herein relate to a device package, wherein the scaffold includes a polymerized photoresist.

In some embodiments, the techniques described herein relate to a device package, wherein the at least one element includes a first device and a second device, wherein the first device includes the first contact pad and the second device includes the second contact pad.

In some embodiments, the techniques described herein relate to a device package, further including a substrate, the first and second devices mounted to the substrate.

In some embodiments, the techniques described herein relate to a device package, further including a first dielectric material, the scaffold embedded in the first dielectric material.

In some embodiments, the techniques described herein relate to a device package, wherein the first device and the second device are embedded in the first dielectric material.

In some embodiments, the techniques described herein relate to a device package, wherein the at least one element includes a substrate, the substrate including the first contact pad.

In some embodiments, the techniques described herein relate to a device package, wherein the substrate includes the second contact pad.

In some embodiments, the techniques described herein relate to a device package, further including a first device mounted to the substrate, the first device including the second contact pad.

In some embodiments, the techniques described herein relate to a device package, further including a first dielectric in which the substrate is at least partially encapsulated, the second contact pad disposed at an outer surface of the first dielectric.

In some embodiments, the techniques described herein relate to a device package, wherein the at least one element includes a die or wafer, the die or wafer including the first and second contact pads.

In some embodiments, the techniques described herein relate to a device package, further including a first device and a second device, wherein the first device and the second device are disposed over the interconnect structure, wherein the interconnect structure is between a substrate and the first device, and wherein the interconnect structure electrically connects the first device with the second device.

In some embodiments, the techniques described herein relate to a device package, further including an encapsulant that encapsulates the first device and the second device.

In some embodiments, the techniques described herein relate to a device package, wherein the interconnect structure is to deliver power or ground to the first device.

In some embodiments, the techniques described herein relate to a device package, wherein the scaffold is rectilinear.

In some embodiments, the techniques described herein relate to a device package, wherein the scaffold includes a lattice structure.

In some embodiments, the techniques described herein relate to a device package, wherein a unit cell topology of the lattice structure includes at least one of a simple cubic, a body-centered cubic, a face-centered cubic, kelvin cell, a diamond, a cubic-diamond, a tetrahedron, an octahedron, and an octet-truss.

In some embodiments, the techniques described herein relate to a device package, further including a coating at an outer surface of the interconnect structure to seal an interior of the interconnect structure, the scaffold being disposed in a fluid.

In some embodiments, the techniques described herein relate to a device package, wherein the fluid is air or a dielectric liquid.

In some aspects, the techniques described herein relate to a device package including: an element; and an interconnect structure disposed over the element, the interconnect structure including: a bulk material including a first dielectric material; and a plurality of struts including a second dielectric material, wherein a subset of the plurality of struts includes a conductive material disposed over the second dielectric material, wherein the bulk material encapsulates the plurality of struts.

In some embodiments, the techniques described herein relate to a device package, further including a first device and a second device, wherein the interconnect structure electrically connects the first device with the second device.

In some embodiments, the techniques described herein relate to a device package, wherein the first dielectric material includes a cured dielectric.

In some embodiments, the techniques described herein relate to a device package, wherein the second dielectric material includes a polymerized photoresist.

In some embodiments, the techniques described herein relate to a device package, wherein the conductive material includes at least one of copper, aluminum, nickel, and gold.

In some embodiments, the techniques described herein relate to a device package, wherein the plurality of struts includes structural wires, wherein the interconnect structure includes between approximately 1 and 100 layers of the structural wires.

In some embodiments, the techniques described herein relate to a device package, wherein the element includes conductive contact pads.

In some embodiments, the techniques described herein relate to a device package, wherein a pitch of the conductive contact pads is between 2 μm and 4 μm.

In some aspects, the techniques described herein relate to an interconnect structure including: a bulk material including a first dielectric material; and a plurality of struts including a second dielectric material, wherein a first subset of the plurality of struts includes a conductive material disposed over the second dielectric material, wherein a second subset of the plurality of struts is not coated with a conductive material, and wherein the bulk material encapsulates the plurality of struts.

In some embodiments, the techniques described herein relate to an interconnect structure, wherein the conductive material includes copper, aluminum, nickel, or gold.

In some embodiments, the techniques described herein relate to an interconnect structure, further including an insulator disposed over the conductive material.

In some embodiments, the techniques described herein relate to an interconnect structure, wherein the second dielectric material includes a polymerized photoresist.

In some embodiments, the techniques described herein relate to an interconnect structure, wherein the plurality of struts includes a lattice structure.

In some embodiments, the techniques described herein relate to an interconnect structure, wherein a unit cell topology of the lattice structure includes at least one of a simple cubic, a body-centered cubic, a face-centered cubic, kelvin cell, a diamond, a cubic-diamond, a tetrahedron, an octahedron, and an octet-truss.

In some embodiments, the techniques described herein relate to an interconnect structure, wherein the subset of the plurality of struts is to electrically connect two or more devices.

In some aspects, the techniques described herein relate to an interconnect structure including: a carrier element having a first surface, wherein the first surface includes a plurality of conductive contact pads; a scaffold including a lattice structure, wherein the lattice structure includes a plurality of struts, wherein the lattice structure is coupled to and extends from at least a portion of the plurality of conductive contact pads, wherein the plurality of struts includes a first dielectric material; and a conductive film disposed over at least a subset of the plurality of struts.

In some embodiments, the techniques described herein relate to an interconnect structure, further including a second dielectric material disposed over the carrier element, wherein the second dielectric material encapsulates the scaffold.

In some embodiments, the techniques described herein relate to an interconnect structure, wherein the scaffold is disposed in a fluid.

In some embodiments, the techniques described herein relate to an interconnect structure, wherein the conductive film is a conformal coating.

In some embodiments, the techniques described herein relate to an interconnect structure, wherein the conductive film includes copper, aluminum, nickel, or gold.

In some embodiments, the techniques described herein relate to an interconnect structure, further including an insulator disposed over the conductive film.

In some embodiments, the techniques described herein relate to an interconnect structure, wherein the scaffold includes a polymerized photoresist.

In some embodiments, the techniques described herein relate to an interconnect structure, wherein the polymerized photoresist is at least partially metallized.

In some embodiments, the techniques described herein relate to an interconnect structure, wherein the scaffold is rectilinear.

In some embodiments, the techniques described herein relate to an interconnect structure, wherein a unit cell topology of the lattice structure includes at least one of a simple cubic, a body-centered cubic, a face-centered cubic, a kelvin cell, a diamond, a cubic-diamond, a tetrahedron an octahedron, and an octet-truss.

In some aspects, the techniques described herein relate to a method of forming a device package, the method including: providing a substrate; providing a photoresist over the substrate; polymerizing a portion of the photoresist with a lithographic process to form a scaffold; and selectively coating the scaffold with a conductive material to form an electrical pathway.

In some embodiments, the techniques described herein relate to a method, wherein selectively coating the scaffold includes activating select surfaces of the scaffold with a laser to prepare the select surfaces for metallization.

In some embodiments, the techniques described herein relate to a method, wherein selectively coating the scaffold includes electroless plating.

In some embodiments, the techniques described herein relate to a method, wherein a first device and a second device are coupled to a surface of the substrate, wherein the photoresist is provided over the first device and the second device, and wherein the electrical pathway electrically connects the first device with the second device.

In some embodiments, the techniques described herein relate to a method, wherein the conductive material includes copper, aluminum, nickel, or gold.

In some embodiments, the techniques described herein relate to a method, further including forming an insulator layer over the conductive material.

In some embodiments, the techniques described herein relate to a method, wherein the substrate includes a plurality of conductive contact pads.

In some embodiments, the techniques described herein relate to a method, further including removing the photoresist that is unpolymerized after polymerizing the portion of the photoresist with the lithographic process to form the scaffold.

In some embodiments, the techniques described herein relate to a method, further including depositing a flowable dielectric over the scaffold and the substrate.

In some embodiments, the techniques described herein relate to a method, further including curing the flowable dielectric.

In some embodiments, the techniques described herein relate to a method, wherein the scaffold is rectilinear.

In some embodiments, the techniques described herein relate to a method, wherein the scaffold includes a lattice structure.

In some embodiments, the techniques described herein relate to a method, wherein a unit cell topology of the lattice structure includes at least one of a simple cubic, a body-centered cubic, a face-centered cubic, a kelvin cell, a diamond, a cubic-diamond, a tetrahedron an octahedron, and an octet-truss.

In some aspects, the techniques described herein relate to a method of forming a device package, the method including: providing a bulk material, wherein a first surface of the bulk material includes a plurality of conductive contact pads; forming a scaffold including a lattice structure, wherein the lattice structure includes a plurality of struts, wherein the lattice structure is coupled to and extends from at least a portion of the plurality of conductive contact pads, wherein the plurality of struts includes a first dielectric material; coating at least a subset of the plurality of struts with a conductive film; and providing a second dielectric material over the bulk material, wherein the second dielectric material encapsulates the scaffold.

In some embodiments, the techniques described herein relate to a method, wherein forming the scaffold includes polymerizing a photoresist.

In some embodiments, the techniques described herein relate to a method, wherein coating at least the subset of the plurality of struts includes preparing the subset of the plurality of struts for selective metallization.

In some embodiments, the techniques described herein relate to a method, further including changing an intensity of a rastering beam in a lithographic process to define a plurality of surface regions of the plurality of struts to be coated with the conductive film.

In some embodiments, the techniques described herein relate to a method, further including defining a plurality of surface regions of the plurality of struts to be coated with the conductive film with orthogonal polymerization or laser-direct structuring.

In some embodiments, the techniques described herein relate to a method, wherein coating at least the subset of the plurality of struts includes providing a conformal coating of the conductive film over at least the subset of the plurality of struts.

In some embodiments, the techniques described herein relate to a method, further including coupling a first device and a second device 112 to the bulk material, wherein the scaffold is formed over the first device and the second device, and wherein the scaffold electrically connects the first device with the second device.

In some embodiments, the techniques described herein relate to a method, further including coupling a first device and a second device to the second dielectric material, wherein the scaffold is between the bulk material and the first device, and wherein the scaffold electrically connects the first device with the second device.

In some embodiments, the techniques described herein relate to a method, further including encapsulating the first device and the second device with an encapsulant.

In some embodiments, the techniques described herein relate to a method, wherein a unit cell topology of the lattice structure includes at least one of a simple cubic, a body-centered cubic, a face-centered cubic, a kelvin cell, a diamond, a cubic-diamond, a tetrahedron, an octahedron, and an octet-truss.

In some aspects, the techniques described herein relate to a method of forming an interconnect structure, the method including: providing a photoresist over a first surface of a carrier element having a plurality of conductive contact pads; forming a lattice structure in the photoresist, the method including: polymerizing a portion of the photoresist with a lithographic process to form a plurality of struts, wherein the plurality of struts includes a polymerized photoresist, wherein the plurality of struts are coupled to and extend from at least a portion of the plurality of conductive contact pads; and selectively coating a subset of the plurality of struts with a conductive film.

In some embodiments, the techniques described herein relate to a method, further including encapsulating the lattice structure with a dielectric material.

In some embodiments, the techniques described herein relate to a method, wherein the conductive film conformally coats the subset of the plurality of struts.

In some embodiments, the techniques described herein relate to a method, wherein the conductive film includes copper, aluminum, nickel, or gold.

In some embodiments, the techniques described herein relate to a method, further including forming an insulator coating over the conductive film.

In some embodiments, the techniques described herein relate to a method, wherein the lattice structure is rectilinear.

In some embodiments, the techniques described herein relate to a method, wherein a unit cell topology of the lattice structure includes at least one of a simple cubic, a body-centered cubic, a face-centered cubic, a kelvin cell, a diamond, a cubic-diamond, a tetrahedron, an octahedron, and an octet-truss.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the apparatus, methods, and systems described herein may be embodied in a variety of other forms; furthermore, various omissions, substitutions, and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

1. A device package comprising:
an interconnect structure comprising an at least partially annular conductive wire disposed about an insulator;
a first contact pad at a first surface of an element, wherein the at least partially annular conductive wire extends from the first contact pad in a direction non-parallel to the first surface and connects to a second contact pad.

2. The device package of claim 1, wherein the interconnect structure comprises a solid dielectric material in which the at least partially annular conductive wire is encapsulated.

3. The device package of claim 1, wherein the at least partially annular conductive wire is disposed in a fluid.

4. (canceled)

5. The device package of claim 1, wherein the insulator comprises a polymer material, the at least partially annular conductive wire comprising a conductive coating disposed about the polymer material.

6. (canceled)

7. The device package of claim 5, wherein the polymer material comprises a polymerized photoresist.

8. The device package of claim 5, wherein a second coating is disposed adjacent to the conductive coating, wherein the second coating comprises a barrier layer.

9. (canceled)

10. The device package of claim 1, wherein the element comprises a first device die, wherein the device package comprises a second device die that includes the second contact pad.

11. (canceled)

12. (canceled)

13. (canceled)

14. (canceled)

15. (canceled)

16. (canceled)

17. (canceled)

18. (canceled)

19. (canceled)

20. The device package of claim 1, wherein the at least partially annular conductive wire is continuous and seamless along a length between the first contact pad and the second contact pad.

21. (canceled)

22. (canceled)

23. (canceled)

24. (canceled)

25. A device package comprising:
at least one element comprising a first contact pad having a first contact surface and a second contact pad having a second contact surface;
an interconnect structure comprising an at least partially annular conductive wire disposed about an insulator, the at least partially annular conductive wire extending between and electrically connecting the first and second contact pads,
wherein the at least partially annular conductive wire connects to the first and second contact pads at respective non-zero angles relative to the first and second contact surfaces, and wherein the at least partially annular conductive wire is continuous and seamless along a length between the first and second contact pads.

26. (canceled)

27. (canceled)

28. (canceled)

29. The device package of claim 25, wherein the insulator comprises a polymer material, the at least partially annular conductive wire comprising a coating disposed about the polymer material, wherein the coating comprises a conductive material.

30. (canceled)

31. (canceled)

32. (canceled)

33. (canceled)

34. (canceled)

35. (canceled)

36. (canceled)

37. (canceled)

38. The device package of claim 25, wherein the at least one element comprises a substrate, and wherein the substrate comprises the second contact pad.

39. (canceled)

40. The device package of claim 38, further comprising a first dielectric material on a first side of the substrate and a second dielectric material on a second side of the substrate opposite the first side, the at least partially annular conductive wire at least partially embedded in the first dielectric material, wherein the second contact pad is disposed at an outer surface of the first dielectric material.

41. (canceled)

42. (canceled)

43. The device package of claim 40, wherein the substrate comprises a transparent substrate and the at least partially annular conductive wire extends through the substrate.

44. (canceled)

45. (canceled)

46. The device package of claim 25, wherein the interconnect structure comprises a scaffold including a plurality of struts, wherein a first subset of struts comprises at least one dielectric material and a conductive coating disposed at least partially about the at least one dielectric material, and wherein a second subset of struts comprises the at least one dielectric material without the conductive coating.

47. (canceled)

48. (canceled)

49. A device package comprising:
an interconnect structure comprising a scaffold, wherein the scaffold comprises an uncoated dielectric structure and a coated polymer structure, wherein the coated polymer structure comprises a first coating, the coated polymer structure to provide a plurality of electrical pathways including a first electrical pathway; and
at least one element including a first contact pad and a second contact pad, wherein the interconnect structure electrically connects the first contact pad with the second contact pad through at least the first electrical pathway.

50. (canceled)

51. (canceled)

52. (canceled)

53. (canceled)

54. (canceled)

55. (canceled)

56. The device package of claim 49, wherein the scaffold comprises a polymerized photoresist, and wherein the first coating comprises a conductive material.

57. The device package of claim 49, wherein the at least one element comprises a first device and a second device, wherein the first device comprises the first contact pad and the second device comprises the second contact pad.

58. (canceled)

59. (canceled)

60. (canceled)

61. (canceled)

62. (canceled)

63. (canceled)

64. (canceled)

65. (canceled)

66. (canceled)

67. (canceled)

68. The device package of claim 57, wherein the interconnect structure is to deliver power or ground to the first device.

69. (canceled)

70. The device package of claim 49, wherein the scaffold comprises a lattice structure.

71. The device package of claim 70, wherein a unit cell topology of the lattice structure comprises at least one of a simple cubic, a body-centered cubic, a face-centered cubic, kelvin cell, a diamond, a cubic-diamond, a tetrahedron, an octahedron, and an octet-truss.

72. (canceled)

73. (canceled)

74. (canceled)

75. (canceled)

76. (canceled)

77. (canceled)

78. (canceled)

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. (canceled)

105. (canceled)

106. (canceled)

107. (canceled)

108. (canceled)

109. (canceled)

110. (canceled)

111. (canceled)

112. (canceled)

113. (canceled)

114. (canceled)

115. (canceled)

116. (canceled)

117. (canceled)

118. (canceled)

119. (canceled)

120. (canceled)

121. (canceled)

122. (canceled)

123. (canceled)

124. (canceled)

125. (canceled)

126. (canceled)

127. (canceled)

128. (canceled)
